(19) United States
(12) Patent Application Publication
(10) Pub. No.: US 2025/0202440 A1
(43) Pub. Date: Jun. 19, 2025

(54) DOHERTY AMPLIFIER CIRCUIT AND SEMICONDUCTOR DEVICE

(71) Applicant: Sumitomo Electric Device Innovations, Inc., Yokohama-shi (JP)

(72) Inventor: Shogo NAGATA, Yokohama-shi (JP)

(73) Assignee: Sumitomo Electric Device Innovations, Inc., Yokohama-shi (JP)

(21) Appl. No.: 18/975,527

(22) Filed: Dec. 10, 2024

(30) Foreign Application Priority Data
Dec. 14, 2023 (JP) 2023-211393

(51) Int. Cl. H03F 1/56; H03F 1/02; H03F 3/213

(52) U.S. Cl. CPC H03F 1/565; H03F 1/0288; H03F 3/213; H03F 2200/222; H03F 2200/387

(57) ABSTRACT

A Doherty amplifier circuit includes a divider dividing a received input signal into a first signal and a second signal, a main amplifier amplifying the first signal and output an amplified signal as a fourth signal, a first peak amplifier amplifying the second signal and output an amplified signal as a fifth signal, a combiner combining the fourth signal and the fifth signal into a combined signal and output the combined signal as an output signal to an output terminal, a first matching circuit connected between the divider and the main amplifier, and a second matching circuit connected between the divider and the first peak amplifier. In an operation band, an absolute value of a return loss seen from the divider toward the second matching circuit is larger than an absolute value of a return loss seen from the divider toward the first matching circuit.

### CROSS REFERENCE TO RELATED APPLICATIONS

This application claims priority based on Japanese Patent Application No. 2023-211393 filed on Dec. 14, 2023, and the entire contents of the Japanese patent application are incorporated herein by reference.

### TECHNICAL FIELD

The present invention relates to a Doherty amplifier circuit and a semiconductor device.

### BACKGROUND

There has been known an N-way (N is three or more) Doherty amplifier circuit using a main amplifier and two or more peak amplifiers (for example, Patent literature 1: U.S. Pat. No. 8,022,760 and Patent literature 2: U.S. Pat. No. 10,601,375).

### SUMMARY

A Doherty amplifier circuit according to an embodiment of the present disclosure includes a divider that divides a received input signal into a first signal and a second signal, a main amplifier that amplifies the first signal and outputs an amplified signal as a fourth signal, a first peak amplifier that amplifies the second signal and outputs an amplified signal as a fifth signal, a combiner that combines the fourth signal and the fifth signal into a combined signal and outputs the combined signal as an output signal to an output terminal, a first matching circuit connected between the divider and the main amplifier, and a second matching circuit connected between the divider and the first peak amplifier. In an operation band, an absolute value of a return loss seen from the divider toward the second matching circuit is larger than an absolute value of a return loss seen from the divider toward the first matching circuit.

A semiconductor device for a Doherty amplifier circuit according to an embodiment of the present disclosure includes a package including a base, a first input lead, and a second input lead; a first semiconductor chip mounted on the base, the first semiconductor chip including a main amplifier that amplifies a first signal divided from an input signal; a second semiconductor chip mounted on the base, the second semiconductor chip comprising a first peak amplifier that amplifies a second signal divided from the input signal; a first capacitor mounted on the base, the first capacitor having a first end electrically connected to the base; a second capacitor mounted on the base, the second capacitor having a first end electrically connected to the base; a third capacitor mounted on the base, the third capacitor having a first end electrically connected to the base; a first inductor having a first end electrically connected to the first input lead and a second end electrically connected to a second end of the first capacitor; a second inductor having a first end electrically connected to the second end of the first capacitor and a second end electrically connected to a second end of the second capacitor; a third inductor having a first end electrically connected to the second end of the second capacitor and a second end electrically connected to an input pad of the first semiconductor chip; a fourth inductor having a first end electrically connected to the second input lead and a second end electrically connected to the second end of the third capacitor; and a fifth inductor having a first end electrically connected to the second end of the third capacitor and a second end electrically connected to an input pad of the second semiconductor chip.

### BRIEF DESCRIPTION OF THE DRAWINGS

FIG. 1 is a block diagram of a Doherty amplifier circuit according to a first embodiment.

FIG. 2 is a circuit diagram of a two-stage matching circuit in the first embodiment.

FIG. 3 is a circuit diagram of a one-stage matching circuit in the first embodiment.

FIG. 4 is a Smith chart illustrating impedance matching of a fundamental harmonic using the one-stage matching circuit in the first embodiment.

FIG. 5 is a Smith chart of a second harmonic using the one-stage matching circuit in the first embodiment.

FIG. 6 is a diagram illustrating efficiency of an impedance Z6(2f) seen from a gate of a transistor toward a front stage with respect to a phase.

FIG. 7 is a Smith chart of the second harmonic using the two-stage matching circuit in the first embodiment.

FIG. 8 is a Smith chart illustrating impedance matching of the fundamental harmonic using the two-stage matching circuit in the first embodiment.

FIG. 9 is a diagram illustrating S11 with respect to a frequency in a simulation.

FIG. 10 is a diagram illustrating S21 with respect to the frequency in the simulation.

FIG. 11 is a circuit diagram of a portion of a Doherty amplifier circuit according to a first comparative example.

FIG. 12 is a circuit diagram of a portion of a Doherty amplifier circuit according to a second comparative example.

FIG. 13 is a circuit diagram of a portion of a Doherty amplifier circuit according to the first embodiment.

FIG. 14 is a circuit diagram of a portion of a Doherty amplifier circuit according to a second embodiment.

FIG. 15 is a diagram illustrating gain with respect to input power in the first comparative example, the second comparative example, the first embodiment, and the second embodiment.

FIG. 16 is a plan view of a semiconductor device according to a third embodiment.

FIG. 17 is a plan view of a semiconductor device according to a first modification of the third embodiment.

### DETAILED DESCRIPTION

However, in the Doherty amplifier circuit, improving efficiency while suppressing distortion is required.

The present disclosure is made in view of the above-mentioned issues and aims to improve characteristics.

### DESCRIPTION OF EMBODIMENTS OF PRESENT DISCLOSURE

First, the contents of embodiments of the present disclosure will be listed and explained.
(1) A Doherty amplifier circuit according to an embodiment of the present disclosure includes a divider that divides a received input signal into a first signal and a second signal, a main amplifier that amplifies the first signal and outputs an amplified signal as a fourth signal, a first peak amplifier that amplifies the second signal and outputs an amplified signal as a fifth signal, a combiner that combines the fourth signal and the fifth signal into a combined signal and outputs the combined signal as an output signal to an output terminal, a first matching circuit connected between the divider and the main amplifier, and a second matching circuit connected between the divider and the first peak amplifier. In an operation band, an absolute value of a return loss seen from the divider toward the second matching circuit is larger than an absolute value of a return loss seen from the divider toward the first matching circuit. Since it is possible to improve the gain of the first peak amplifier, the distortion can be suppressed. Thus, the characteristics can be improved.
(2) In (1), at a frequency twice a center frequency of the operation band, an impedance seen from the main amplifier toward the first matching circuit may be capacitive, and at the frequency twice the center frequency, an impedance seen from the first peak amplifier toward the second matching circuit may be inductive. Since efficiency is improved, the characteristics can be further improved.
(3) In (2), the first matching circuit may be a two-stage matching circuit that includes a first inductor having a first end electrically connected to the divider and a second end electrically connected to a first node, a second inductor having a first end electrically connected to the first node and a second end electrically connected to a second node, a third inductor having a first end electrically connected to the second node and a second end electrically connected to the main amplifier, a first capacitor shunt-connected to the first node, and a second capacitor shunt-connected to the second node, and the second matching circuit may be a one-stage matching circuit that includes a fourth inductor having a first end electrically connected to the divider and a second end electrically connected to a third node, a fifth inductor having a first end electrically connected to the third node and a second end electrically connected to the first peak amplifier, and a third capacitor shunt-connected to the third node. Thus, the characteristics can be further improved.
(4) In (3), when, in the operation band, a ratio of an absolute value of a second impedance seen from the first inductor toward the first node to an absolute value of a first impedance seen from the third inductor toward the main amplifier is a first ratio, a ratio of an absolute value of a third impedance seen from the divider toward the first inductor to the absolute value of the second impedance is a second ratio, a ratio of an absolute value of a fifth impedance seen from the fourth inductor toward the third node to an absolute value of a fourth impedance seen from the fifth inductor toward the first peak amplifier is a third ratio, and a ratio of an absolute value of a sixth impedance seen from the divider toward the fourth inductor to the absolute value of the fifth impedance is a fourth ratio, a ratio of the first ratio to the second ratio may be larger than a ratio of the third ratio to the fourth ratio. Thus, it is possible to improve the gain of the peak amplifier.
(5) In (4), the first ratio may be larger than the second ratio. Thus, the efficiency of the main amplifier can be improved.
(6) In any one of (1) to (5), the Doherty amplifier circuit may further include a second peak amplifier that amplifies a third signal and outputs an amplified signal as a sixth signal, and a third matching circuit connected between the divider and the second peak amplifier. An input power of the input signal for turning on the second peak amplifier may be larger than an input power of the input signal for turning on the first peak amplifier. The divider may be divide the input signal into the first signal, the second signal, and the third signal. The combiner may combine the fourth signal, the fifth signal, and the sixth signal into a combined signal and output the combined signal as the output signal to the output terminal. Thus, it is possible to improve the characteristics when there are two or more peak amplifiers.
(7) In (6), in the operation band, an absolute value of a return loss seen from the divider toward the third matching circuit may be larger than an absolute value of a return loss seen from the divider toward the first matching circuit. Thus, the distortion can be further suppressed.
(8) In (7), at a frequency twice a center frequency of the operation band, an impedance seen from the main amplifier toward the first matching circuit may be capacitive, at the frequency twice the center frequency, an impedance seen from the first peak amplifier toward the second matching circuit may be inductive, and at the frequency twice the center frequency, an impedance seen from the second peak amplifier toward the third matching circuit may be inductive. Thus, the distortion can be further suppressed.
(9) In (6), in the operation band, an absolute value of a return loss seen from the divider toward the third matching circuit may be smaller than an absolute value of a return loss seen from the divider toward the second matching circuit. Thus, the efficiency can be improved.
(10) In (9), at a frequency twice a center frequency of the operation band, an impedance seen from the main amplifier toward the first matching circuit may be capacitive, at the frequency twice the center frequency, an impedance seen from the first peak amplifier toward the second matching circuit may be inductive, and at the frequency twice the center frequency, an impedance seen from the second peak amplifier toward the third matching circuit may be capacitive. Thus, the efficiency can be further improved.
(11) A semiconductor device for a Doherty amplifier circuit according to an embodiment of the present disclosure includes a package including a base, a first input lead, and a second input lead; a first semiconductor chip mounted on the base, the first semiconductor chip including a main amplifier that amplifies a first signal divided from an input signal; a second semiconductor chip mounted on the base, the second semiconductor chip including a first peak amplifier that amplifies a second signal divided from the input signal; a first capacitor mounted on the base, the first capacitor having a first end electrically connected to the base; a second capacitor mounted on the base, the second capacitor having a first end electrically connected to the base; a third capacitor mounted on the base, the third capacitor having a first end electrically connected to the base; a first inductor having a first end electrically connected to the first input lead and a second end electrically connected to a second end of the first capacitor; a second inductor having a first end electrically connected to the second end of the first capacitor and a second end electrically connected to a second end of the second capacitor; a third inductor having a first end electrically connected to the second end of the second capacitor and a second end electrically connected to an input pad of the first semiconductor chip; a fourth inductor having a first end electrically connected to the second input lead and a second end electrically connected to the second end of the third capacitor; and a fifth inductor having a first end electrically connected to the second end of the third capacitor and a second end electrically connected to an input pad of the second semiconductor chip. Thus, the characteristics can be improved.

### Details of Embodiments of Present Disclosure

Specific examples of a Doherty amplifier circuit and a semiconductor device according to embodiments of the present disclosure will be described below with reference to the drawings. The present disclosure is not limited to these examples, but is defined by the scope of the claims, and is intended to include all modifications within the scope and meaning equivalent to the scope of the claims.

### First Embodiment

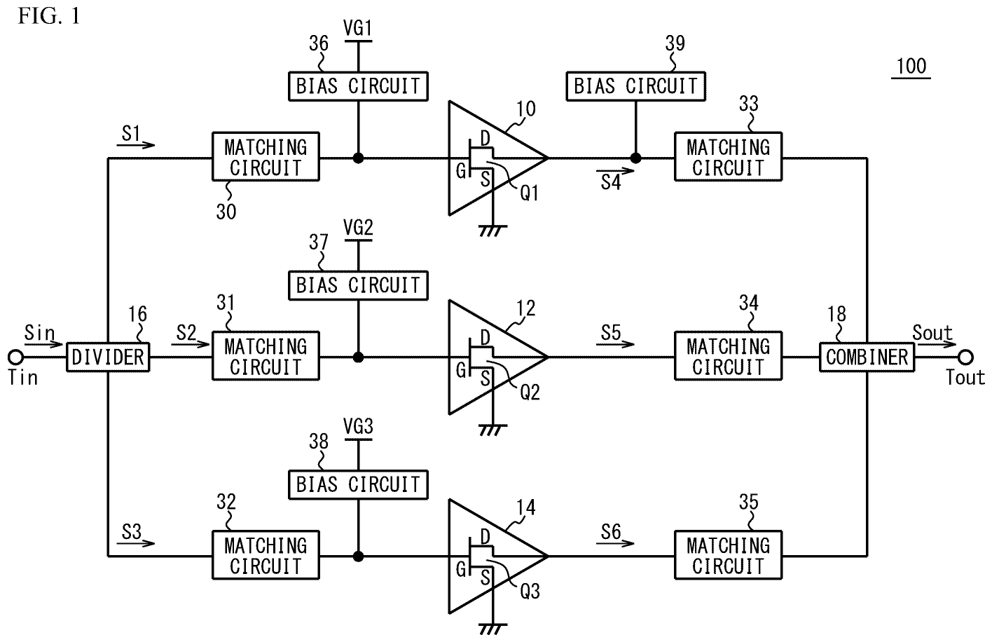

A high-output high-frequency amplifier circuit used in a base station of mobile communication will be described as an example of the Doherty amplifier circuit. In this case, the frequency of the high-frequency signal is, for example, 0.5 GHz to 20 GHz. FIG. 1 is a block diagram of a Doherty amplifier circuit according to a first embodiment.

As illustrated in FIG. 1, in a Doherty amplifier circuit 100, a main amplifier 10, a peak amplifier 12 (first peak amplifier), and a peak amplifier 14 (second peak amplifier) are connected in parallel between a divider 16 and a combiner 18. Thus, Doherty amplifier circuit 100 is a three-way amplifier circuit. The Doherty amplifier circuit may be an N-way Doherty amplifier circuit having one or three or more peak amplifiers.

A high-frequency signal is input to an input terminal Tin as an input signal Sin. Divider 16 divides input signal Sin input to input terminal Tin into signals S1 (first signal), S2 (second signal), and S3 (third signal). Divider 16 is, for example, a Wilkinson-type divider.

A path to which signal S1 is input includes a matching circuit 30, a bias circuit 36, main amplifier 10, a bias circuit 39, and a matching circuit 33. A path to which signal S2 is input includes a matching circuit 31, a bias circuit 37, peak amplifier 12, and a matching circuit 34. A path to which signal S3 is input includes a matching circuit 32, a bias circuit 38, peak amplifier 14, and a matching circuit 35.

Matching circuits 30 to 32 match impedances seen from divider 16 toward matching circuits 30 to 32 with impedances seen from matching circuits 30 to 32 toward main amplifier 10, peak amplifier 12 and 14, respectively. Bias circuits 36 to 38 supply gate bias voltages VG1 to VG3 to gates G of main amplifier 10 and peak amplifiers 12 and 14, respectively, and suppress the leakage of signals S1 to S3 to bias terminals.

Main amplifier 10 and peak amplifiers 12 and 14 amplify signals S1, S2 and S3, respectively, and output the amplified signals S4 (fourth signal), S5 (fifth signal) and S6 (sixth signal), respectively. Bias circuit 39 supplies a drain bias voltage VD to drains D of main amplifier 10 and peak amplifiers 12 and 14, and suppresses the leakage signal S4 to the bias terminal. Matching circuits 33 to 35 match impedances seen from main amplifier 10, peak amplifiers 12 and 14 toward matching circuits 33 to 35 with impedances seen from matching circuits 33 to 35 toward combiners 18, respectively. Combiner 18 combines signals S4 to S6 and outputs the combined signal to an output terminal Tout as an output signal Sout.

Main amplifier 10 and peak amplifiers 12 and 14 include transistors Q1 to Q3, respectively. Transistors Q1 to Q3 are, for example, field effect transistors (FETs), and are, for example, gallium nitride high electron mobility transistors (GaN HEMTs) or laterally diffused metal oxide semiconductors (LDMOSs). Sources S of transistors Q1 to Q3 are grounded, signals S1 to S3 are input to gates G, and signals S4 to S6 are output from drains D.

When the input power of input signal Sin increases, main amplifier 10 starts to operate. Peak amplifiers 12 and 14 do not operate until the input power reaches a level at which main amplifier 10 starts to be saturated, and main amplifier 10 amplifies the input signal. Peak amplifier 12 starts operating at the input power at which main amplifier 10 starts to be saturated. Peak amplifier 14 does not operate until the input power at which peak amplifier 12 starts to be saturated, and main amplifier 10 and peak amplifier 12 amplify the input signal. Peak amplifier 14 starts operating at the input power at which peak amplifier 12 starts to be saturated. Thereafter, main amplifier 10 and peak amplifiers 12 and 14 amplify input signal Sin. As described above, the input power for turning on peak amplifier 12 is larger than the input power for turning on main amplifier 10, and the input power for turning on peak amplifier 14 is larger than the input power for turning on peak amplifier 12. Main amplifier 10 is, for example, an A-class or AB-class amplifier, and peak amplifiers 12 and 14 are, for example, C-class amplifiers.

In the first embodiment, the absolute value of a return loss seen from divider 16 toward matching circuit 30 is smaller than the absolute value of a return loss seen from divider 16 toward matching circuit 31. Thus, the gain of main amplifier 10 is lower than the gain of peak amplifier 12. On the other hand, the efficiency of main amplifier 10 is higher than the efficiency of peak amplifier 12. The absolute value of a return loss seen from divider 16 toward matching circuit 32 is larger than the absolute value of the return loss seen from divider 16 toward matching circuit 30. It is noted that, a return loss RL seen from divider 16 toward matching circuits 30 and 32 is expressed as RL=20 log₁₀|Γ|[dB] using a reflection coefficient |Γ| seen from divider 16 toward matching circuits 30 and 32 in an operation band. Here, the reflection coefficient |Γ| corresponds to an absolute value |S11| of S-parameter S11, and it is defined as |Γ|=|(Z−Z₀)/(Z+Z₀)|, where Z is the impedance seen from divider 16 toward matching circuits 30 to 32 in the operation band, and Z₀ is a reference impedance.

### Example of Matching Circuit

As examples of matching circuits 30 to 32, a two-stage matching circuit 30a and a one-stage matching circuit 30b will be described. Two-stage matching circuit 30a and one-stage matching circuit 30b are merely examples, and the circuit configuration is not limited to two-stage matching circuit 30a and one-stage matching circuit 30b.

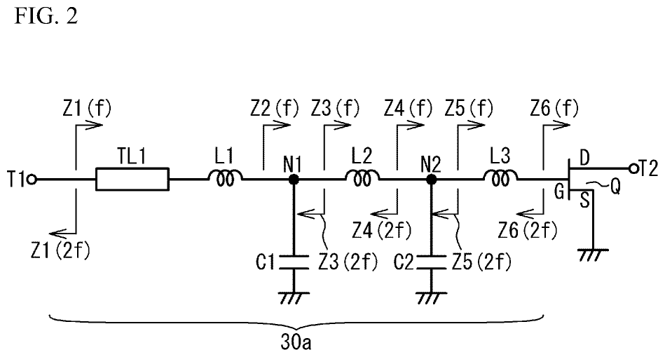

FIG. 2 is a circuit diagram of a two-stage matching circuit in the first embodiment. A terminal T1 is the output terminal of divider 16 illustrated in FIG. 1. A terminal T2 is the output terminal of transistors Q (corresponding to transistors Q1 to Q3 in FIG. 1) used in main amplifier 10 and peak amplifiers 12 and 14. Source S of transistor Q is grounded, and drain D is electrically connected to terminal T2.

Two-stage matching circuit 30a includes a transmission line TL1, inductors L1 to L3, and capacitors C1 and C2. Transmission line TL1 corresponds to, for example, a line provided on a circuit board. A first end of inductor L1 (first inductor) is electrically connected to terminal T1 through transmission line TL1, and a second end of inductor L1 (first inductor) is electrically connected to a node N1 (first node). A first end of inductor L2 (second inductor) is electrically connected to node N1, and a second end of inductor L2 (second inductor) is electrically connected to a node N2 (second node). A first end of inductor L3 (third inductor) is electrically connected to node N2, and a second end of inductor L3 (third inductor) is electrically connected to gate G of transistor Q. Capacitor C1 (first capacitor) is shunt-connected to node N1. Capacitor C2 (second capacitor) is shunt-connected to node N2.

The impedances of fundamental harmonics (signals of the operation band) seen from terminal T1, inductor L1, node N1, inductor L2, node N2, and inductor L3 toward transistor Q are denoted by Z1(f), Z2(f), Z3(f), Z4(f), Z5(f), and Z6(f), respectively. The impedances of second harmonics (signals twice the frequency of the operation band) seen from gate G, inductor L3, node N2, inductor L2, and transmission line TL1 toward terminal T1 are denoted by Z6(2f), Z5(2f), Z4(2f), Z3(2f), and Z1(2f), respectively.

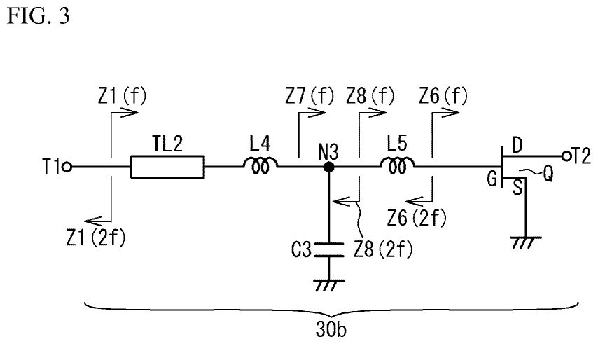

FIG. 3 is a circuit diagram of a one-stage matching circuit in the first embodiment. One-stage matching circuit 30b includes a transmission line TL2, inductors L4 and L5, and a capacitor C3. Transmission line TL2 corresponds to, for example, a line provided on a circuit board. A first end of inductor L4 (fourth inductor) is electrically connected to terminal T1 through transmission line TL2, and a second end of inductor L4 (fourth inductor) is electrically connected to a node N3 (third node). A first end of inductor L5 (fifth inductor) is electrically connected to node N3, and a second end of inductor L5 (fifth inductor) is electrically connected to gate G of transistor Q. Capacitor C3 (third capacitor) is shunt-connected to node N3.

The impedances of the fundamental harmonic seen from terminal T1, inductor L4, node N3, and inductor L5 toward transistor Q are denoted by Z1(f), Z7(f), Z8(f), and Z6(f), respectively. The impedances of the second harmonic seen from gate G, inductor L5, and transmission line TL2 toward terminal T1 are denoted by Z6(2f), Z8(2f), and Z1(2f), respectively.

### [Description of Impedance Matching by Matching Circuit]

Impedance matching will be described using two-stage matching circuit 30a and one-stage matching circuit 30b. The impedance matching method is not limited to the method described below.

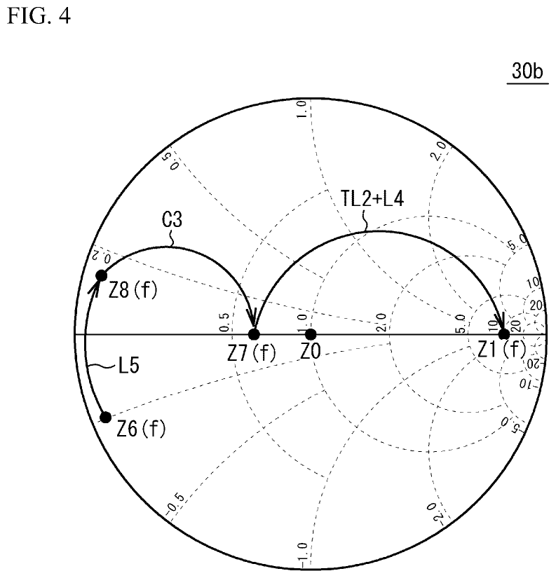

FIG. 4 is a Smith chart illustrating impedance matching of a fundamental harmonic using a one-stage matching circuit in the first embodiment. For the sake of easy understanding of FIG. 4, a reference impedance Z0 is set to 5Ω for convenience. An impedance Z1(f) seen from terminal T1 toward one-stage matching circuit 30b is 50Ω, and is located substantially on a real axis. In an example in which a GaN HEMT is used as transistor Q, the absolute value of an impedance Z6(f) seen from one-stage matching circuit 30b toward gate G is 0.15Ω, and transistor Q is capacitive. Inductor L5 converts impedance Z6(f) into an impedance Z8(f). Capacitor C3 converts impedance Z8(f) into an impedance Z7(f) substantially on the real axis. Transmission line TL2 and inductor L4 convert impedance Z7(f) into an impedance Z1(f).

For example, in a GaN HEMT in which the operation band is the 2 GHz band and the maximum power is 200 W, the absolute value of impedance Z6(f) is 0.15Ω. As described above, the absolute value of the input impedance of the transistor having a large output power is low. On the other hand, impedance Z1(f) corresponding to the output impedance of divider 16 is 50Ω. Thus, the absolute value of impedance Z1(f) with respect to the absolute value of impedance Z6(f) is approximately 300 times.

As a method of converting impedance Z6(f) into impedance Z1(f), it is considered that impedance Z6(f) is converted into an impedance on the real axis in which an absolute value is not substantially changed and then the impedance is converted from 0.15Ω into 50Ω by using an impedance converter of a ¼ wavelength line. However, when the impedance is converted from 0.15Ω into 50Ω by using the ¼ wavelength line, the impedance conversion ratio becomes about 300 times, and it is difficult to achieve matching in a wide band.

Thus, in one-stage matching circuit 30b, impedance Z7(f) is set to about 3Ω substantially on the real axis. Thus, Z7(f) is set to about √(Z6(f)×Z1(f)). Thus, the conversion from impedance Z6(f) to Z1(f) via Z7(f) is realized by performing impedance conversion twice, from 0.15Ω to 50Ω via 3Ω, which is approximately 20 times. When absolute values of impedances Z6(f), Z7(f), and Z1(f) are 0.15 Ω, 3Ω, and 50Ω, respectively, impedance conversion ratios |Z7(f)|/|Z6(f)|=20 and |Z1(f)|/|Z7(f)|=16.7 are obtained. In this way, the impedance conversion ratios |Z7(f)|/|Z6(f)| and |Z1(f)|/|Z7(f)| can be reduced, and thus the bandwidth can be widened.

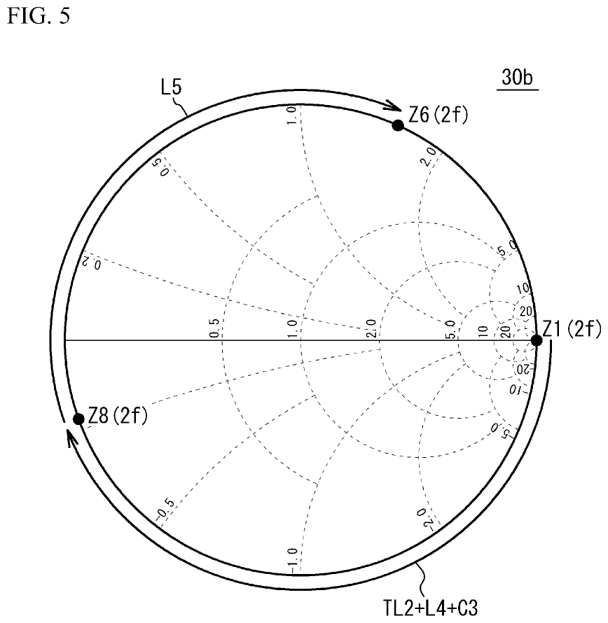

FIG. 5 is a Smith chart of a second harmonic using a one-stage matching circuit in the first embodiment. As illustrated in FIG. 5, it is required to prevent the signal of the second harmonic from leaking to divider 16. Thus, an impedance Z1(2f) is substantially open. Transmission line TL2, inductor L4, and capacitor C3 convert impedance Z1(2f) into an impedance Z8(2f) on the outer circumference of the Smith chart. Further, inductor L5 converts impedance Z8(2f) into an impedance Z6(2f) on the outer circumference of the Smith chart. Impedance Z6(2f) is inductive.

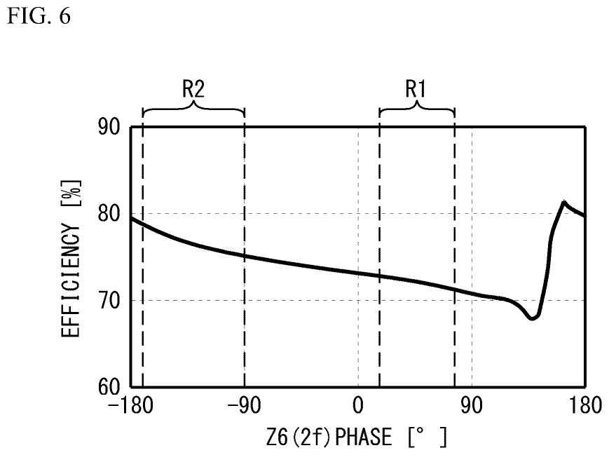

FIG. 6 is a graph illustrating efficiency of impedance Z6(2f) seen from the gate of the transistor toward the front stage with respect to a phase. The GaN HEMT in which the operation band is the 2 GHz band and the maximum power is 200 W is illustrated as an example. The phase of impedance Z6(2f) on the horizontal axis is the phase on the Smith chart of FIG. 5. The open position indicates that the phase is 0°, and when the phase increases from 0°, impedance Z6(2f) rotates counterclockwise around the center of the Smith chart. When the phase becomes smaller from 0°, impedance Z6(2f) rotates clockwise around the center of the Smith chart. The phase of the position of the short is 180° and −180°. The efficiency of the vertical axis is drain efficiency.

As illustrated in FIG. 6, the efficiency is lowest when the phase is around 130°, is highest when the phase is around 150°, and increases as the phase moves from 130° to 150° through −180°. In a range R1 where the phase is in the vicinity of 20° to 70°, the efficiency is reduced. On the other hand, in a range R2 where the phase is from −90° to −180°, the efficiency is improved. As described above, in order to improve the efficiency, it is important to adjust the phase of the second harmonic as well as to match the impedance of the fundamental harmonic as illustrated in FIG. 4.

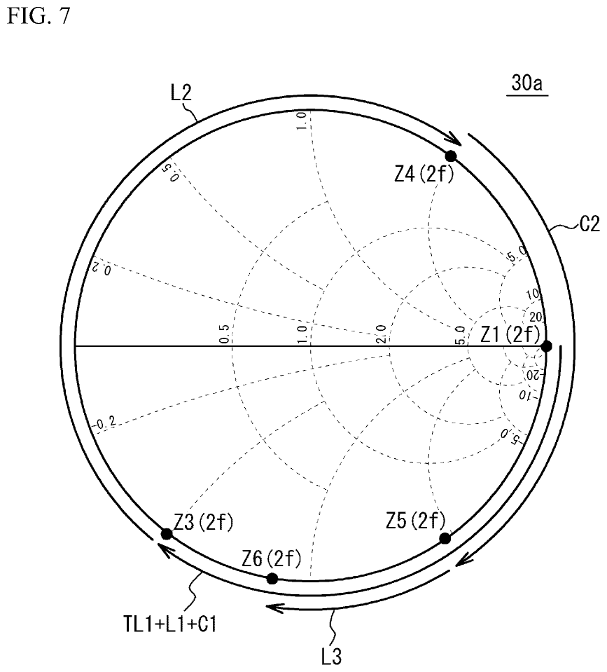

Thus, the following description will discuss that the efficiency is improved by using two-stage matching circuit 30a. FIG. 7 is the Smith chart of the second harmonic using a two-stage matching circuit in the first embodiment. As illustrated in FIG. 7, transmission line TL1, inductor L1 and capacitor C1 convert impedance Z1(2f) at the open position to an impedance Z3(2f) on the outer circumference of the Smith chart. Further, inductor L2 converts impedance Z3(2f) into an impedance Z4(2f) on the outer circumference of the Smith chart. The position of impedance Z4(2f) is substantially the same as the position of impedance Z6(2f) in FIG. 5. Capacitor C2 converts impedance Z4(2f) to an impedance Z5(2f) on the outer circumference of the Smith chart. Inductor L3 converts impedance Z5(2f) into impedance Z6(2f) on the outer circumference of the Smith chart. In this way, by providing capacitor C2 and inductor L3, impedance Z6(2f) can be capacitive. Thus, the efficiency can be improved.

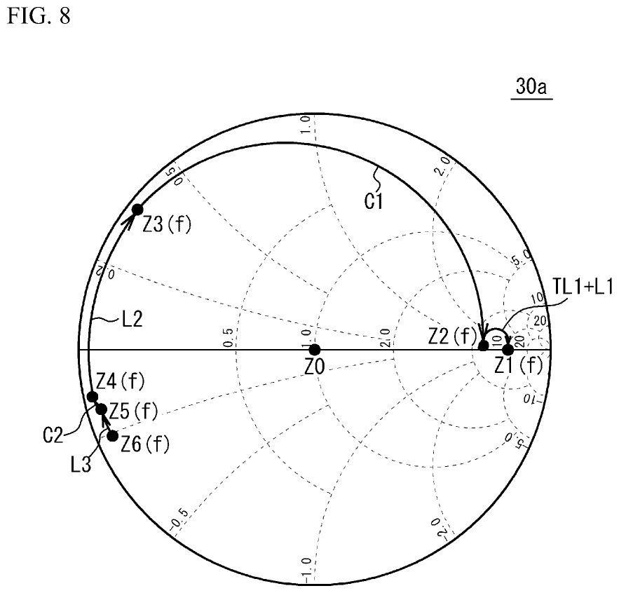

FIG. 8 is the Smith chart illustrating impedance matching of the fundamental harmonic using the two-stage matching circuit in the first embodiment. As illustrated in FIG. 8, in two-stage matching circuit 30a, inductor L3 of FIG. 2 converts impedance Z6(f) into an impedance Z5(f). Capacitor C2 converts impedance Z5(f) into an impedance Z4(f). Inductor L2 converts impedance Z4(f) into an impedance Z3(f). Capacitor C1 converts impedance Z3(f) into an impedance Z2(f). Transmission line TL1 and inductor L1 convert impedance Z2(f) into impedance Z1(f). Thus, impedance Z6(f) can be converted into impedance Z1(f).

When impedance Z6(2f) of the second harmonic is made capacitive as illustrated in FIG. 7 and impedance Z6(f) of the fundamental harmonic is converted into impedance Z1(f) as illustrated in FIG. 8, inductor L3 and capacitor C2 are made small and impedances Z5(f) and Z4(f) are not moved much from impedance Z6(f). By making inductor L2 larger, impedance Z4(2f) in FIG. 7 is largely rotated, but impedance Z3(f) in FIG. 8 is also rotated near the outer circumference. When impedance Z2(f) is converted from impedance Z3(f) to a value on the real axis by using capacitor C1, impedance Z2(f) becomes closer to impedance Z1(f). In one example, impedance Z2(f) is 30 Ω.

When absolute values of impedances Z6(f), Z2(f), and Z1(f) are 0.15 Ω, 30Ω, and 50Ω, respectively, impedance conversion ratios |Z2(f)|/|Z6(f)|=200 and |Z1(f)|/|Z2(f)|=1.7 are obtained. Thus, the impedance conversion ratio is unbalanced. Thus, it is difficult to achieve a wide band.

As described above, when two-stage matching circuit 30a is used, the efficiency is high but the band is narrow. When the gain is to be obtained in the entire operation band by using two-stage matching circuit 30a, matching is performed so that the entire gain is reduced, and the gain is reduced. When one-stage matching circuit 30b is used, the efficiency is low but the bandwidth is wide. Thus, it is easy to obtain a gain in the entire operation band, and the gain is improved.

### [Simulation]

The simulation was performed on S11 and S21 at terminals T1 and T2 in the case where two-stage matching circuit 30a of FIG. 2 and one-stage matching circuit 30b of FIG. 3 were used as the matching circuits. The simulation conditions are as follows.
Transistor Q: GaN HEMT
Two-stage matching circuit 30a:
Transmission line TL1: Characteristics impedance: 19 Ω,
Electrical length: 87° Inductors L1, L2, L3: 0.1 nH, 0.2 nH, 0.022 nH
Capacitors C1, C2: 42 pF, 20 pF
One-stage matching circuit 30b:
Transmission line TL2: Characteristics impedance: 8Ω, Electrical length: 83°
Inductor L4, L5: 0.1 nH, 0.137 nH
Capacitor C3: 108 pF
Operation band: 1.8 Hz to 2.2 GHz
The electrical length is converted into a phase of 2 GHz.

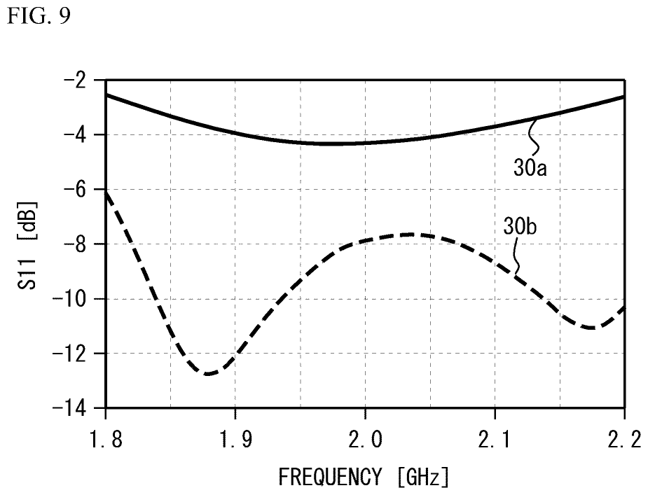

FIG. 9 is a diagram illustrating S11 with respect to a frequency in the simulation. The frequency on the horizontal axis is the frequency of the high-frequency signal input to terminal T1. S11 on the vertical axis represents the absolute value of S-parameter S11 of terminal T1, which corresponds to the absolute value of the reflection coefficient. Further, S11 corresponds to the return loss, and the absolute value of the return loss is small when S11 is close to 0 dB, and the absolute value of the return loss is large when S11 is close to 0, that is, when the negative dB value is large. The figure illustrates the case where two-stage matching circuit 30a is used and the case where one-stage matching circuit 30b is used.

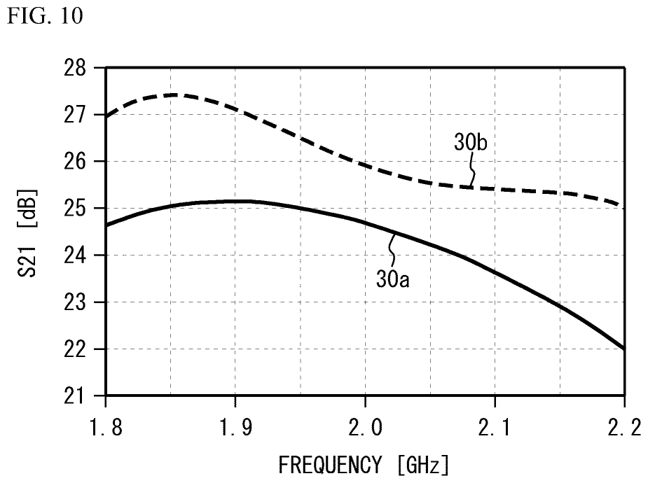

FIG. 10 is a diagram illustrating S21 with respect to the frequency in the simulation. S21 on the vertical axis represents the absolute value of S-parameter S21 from terminal T1 to terminal T2, and is the transmission characteristics. S21 corresponds to the gain, and when S21 is large, the gain is large.

As illustrated in FIG. 9, when one-stage matching circuit 30b is used, the absolute value of the return loss is larger than that when two-stage matching circuit 30a is used. Thus, as illustrated in FIG. 10, the gain is at least 1 dB or more in the entire operation band.

### Comparison of Comparative Example and Embodiment

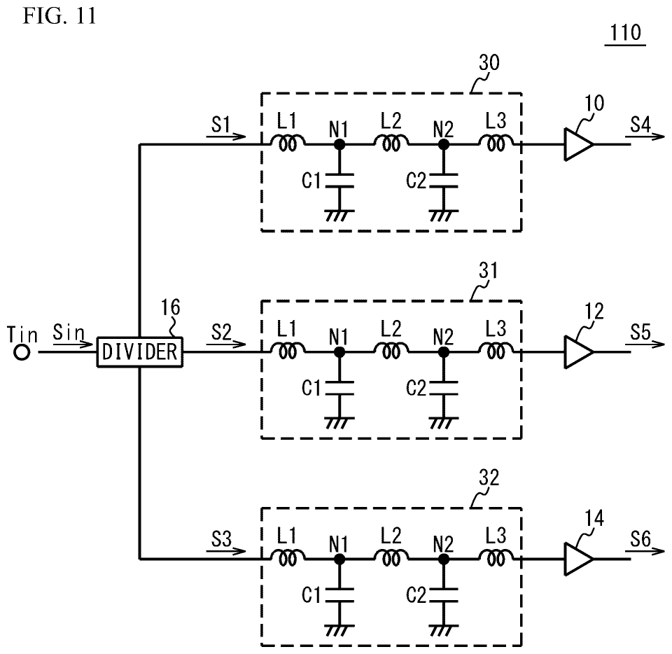

FIGS. 11, 12, 13 and 14 are circuit diagrams of a portion of the Doherty amplifier circuit according to a first comparative example, a second comparative example, the first embodiment and a second embodiment, respectively. In FIGS. 11 to 14, divider 16, matching circuits 30 to 32, main amplifier 10, and peak amplifiers 12 and 14 are illustrated.

As illustrated in FIG. 11, in a Doherty amplifier circuit 110 of the first comparative example, matching circuits 30 to 32 are two-stage matching circuits 30a having inductors L1 to L3 and capacitors C1 and C2.

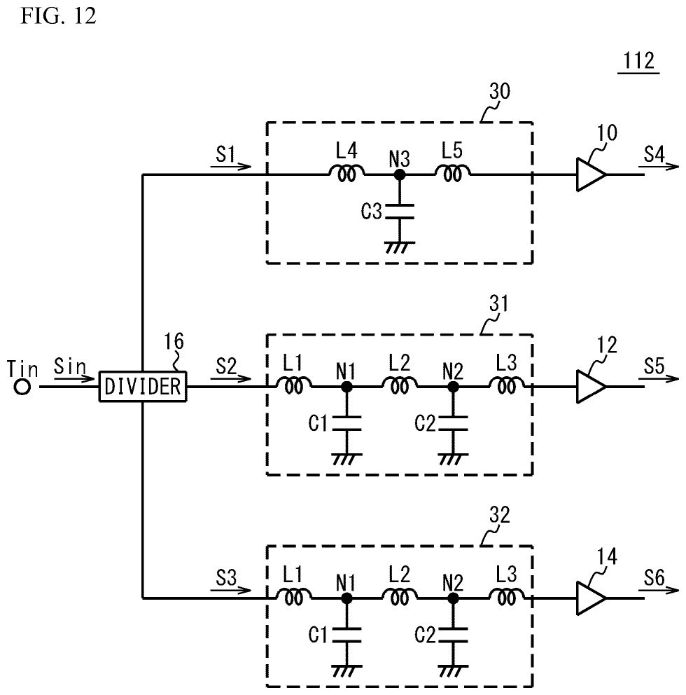

As illustrated in FIG. 12, in a Doherty amplifier circuit 112 of the second comparative example, matching circuit 30 is one-stage matching circuit 30b having inductors L4 and L5 and capacitor C3. Each of matching circuits 31 and 32 is two-stage matching circuit 30a having inductors L1 to L3 and capacitors C1 and C2.

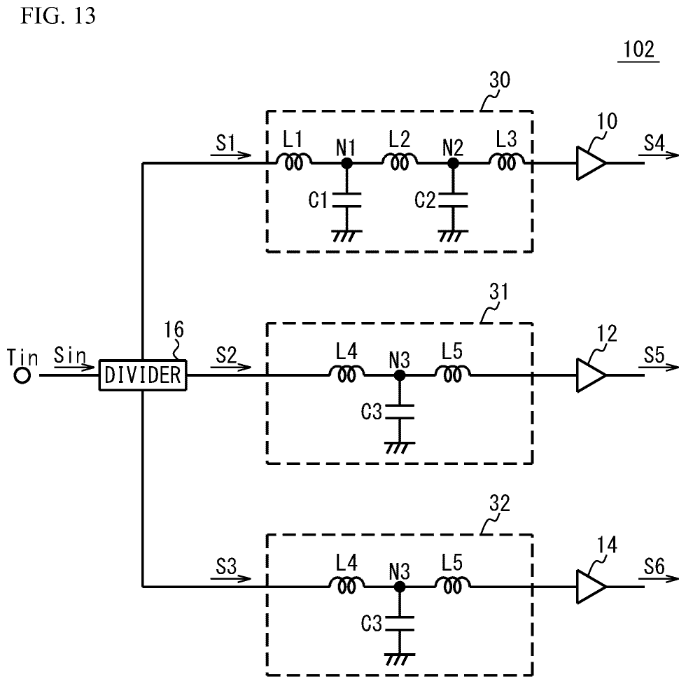

As illustrated in FIG. 13, in a Doherty amplifier circuit 102 of the first embodiment, matching circuit 30 is two-stage matching circuit 30a having inductors L1 to L3 and capacitors C1 and C2. Each of matching circuits 31 and 32 is one-stage matching circuit 30b having inductors L4 and L5 and capacitor C3.

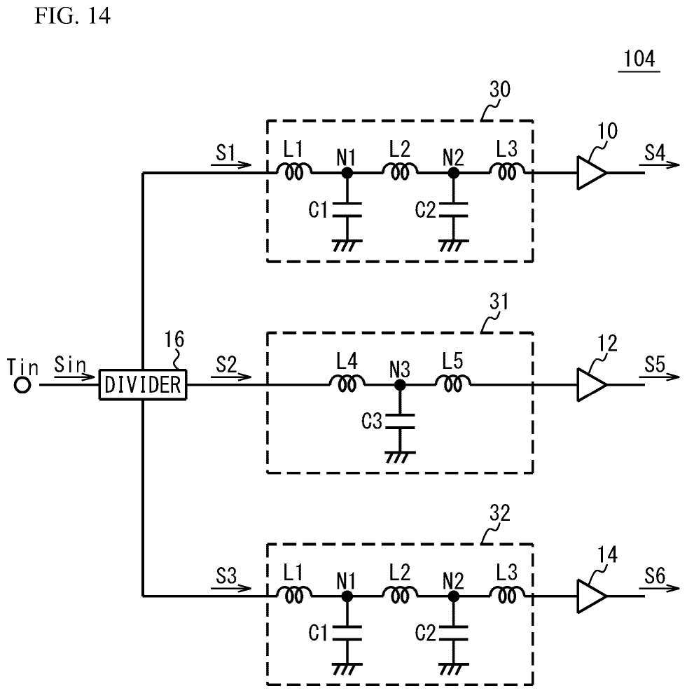

As illustrated in FIG. 14, in a Doherty amplifier circuit 104 of the second embodiment, each of matching circuits 30 and 32 is two-stage matching circuit 30a having inductors L1 to L3 and capacitors C1 and C2. Matching circuit 31 is one-stage matching circuit 30b having inductors L4 and L5 and capacitor C3.

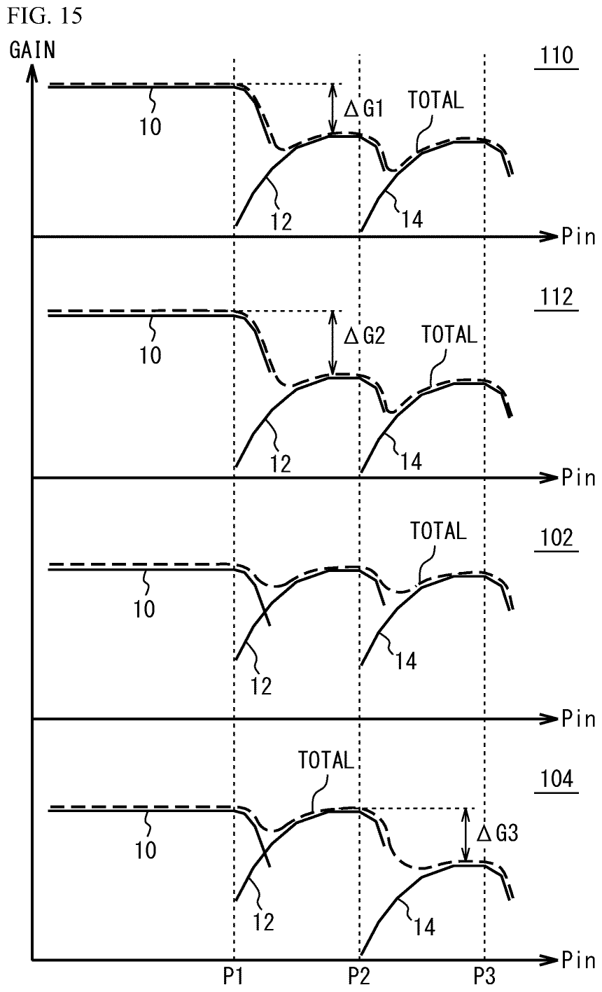

FIG. 15 is a diagram illustrating gain with respect to input power in the first comparative example, the second comparative example, the first embodiment and the second embodiment. The horizontal axis corresponds to an input power Pin of input signal Sin. The gain on the vertical axis is power gain, and is different from S21 of the small signal in FIG. 10, but the power gain increases as S21 increases. The solid line represents the gain of main amplifier 10 and peak amplifiers 12 and 14, while the combined dashed line represents the total gain of the whole of main amplifier 10 and peak amplifiers 12 and 14.

As illustrated in FIG. 15, in Doherty amplifier circuit 110 of the first comparative example, in order to increase the efficiency, two-stage matching circuits 30a are used as matching circuits 30 to 32 as illustrated in FIG. 11. In a range where input power Pin is up to a power P1, the gain of main amplifier 10 is substantially constant. When input power Pin becomes larger than power P1, main amplifier 10 is saturated and the gain of main amplifier 10 is reduced.

Peak amplifier 12 starts operating around power P1. When input power Pin increases from power P1, the gain of peak amplifier 12 gradually increases and is saturated at a power P2. The gain of peak amplifier 12 when peak amplifier 12 is saturated is smaller than that of main amplifier 10 when main amplifier 10 is saturated. When the input power becomes larger than power P2, peak amplifier 12 is saturated and the gain of peak amplifier 12 is reduced.

Peak amplifier 14 starts operating around power P2. When the input power Pin increases from power P2, the gain of peak amplifier 14 gradually increases and is saturated at a power P3. The gain of peak amplifier 14 when peak amplifier 14 is saturated is smaller than that of main amplifier 10 when main amplifier 10 is saturated. When the input power becomes larger than power P3, peak amplifier 14 is saturated, and the gain of peak amplifier 14 is reduced.

The gain behavior of main amplifier 10 is different from that of peak amplifiers 12 and 14 because main amplifier 10 is an amplifier of class-AB operation and peak amplifiers 12 and 14 are amplifiers of class-C operation.

The total gain is substantially constant in a range where input power Pin is up to power P1. When input power Pin becomes larger than power P1, the total gain decreases with a decrease in the gain of main amplifier 10, and then increases with an increase in the gain of peak amplifier 12, and becomes substantially constant. When input power Pin becomes larger than power P2, the total gain decreases with a decrease in the gain of peak amplifier 12, and then increases with an increase in the gain of peak amplifier 14, and becomes substantially constant. When input power Pin becomes larger than power P3, the total gain decreases with a decrease in the gain of peak amplifier 14.

In the first comparative example, a step of ΔG1 is formed in the total gain due to the difference in gain between main amplifier 10 and peak amplifiers 12 and 14. When the gain is constant with respect to input power Pin, linearity of amplitude-modulation (AM)/AM characteristics or the like is good. In the first comparative example, since step ΔG1 is formed, the AM/AM characteristics are deteriorated and the distortion characteristics are degraded.

In Doherty amplifier circuit 112 of the second comparative example, as illustrated in FIG. 12, one-stage matching circuit 30b is used as matching circuit 30, and two-stage matching circuit 30a is used as matching circuits 31 and 32. As illustrated in FIG. 15, the gain of main amplifier 10 is larger than that of Doherty amplifier circuit 110 of the first comparative example. As a result, a step ΔG2 of the total gain around power P2 of the input power Pin becomes larger than ΔG1. Thus, the AM/AM characteristics are deteriorated compared to Doherty amplifier circuit 110 of the first comparative example. Further, by using one-stage matching circuit 30b in the matching circuit 30, the efficiency of main amplifier 10 decreases.

In Doherty amplifier circuit 102 of the first embodiment, as illustrated in FIG. 13, two-stage matching circuit 30a is used as matching circuit 30, and one-stage matching circuit 30b is used as matching circuits 31 and 32. As illustrated in FIG. 15, the gains of peak amplifiers 12 and 14 are larger than those of Doherty amplifier circuit 110 of the first comparative example. Thus, the step of the total gain around power P2 of input power Pin is reduced. Thus, the AM/AM characteristics are improved compared to Doherty amplifier circuit 110 of the first comparative example. By using one-stage matching circuit 30b in matching circuits 31 and 32, the efficiency of peak amplifiers 12 and 14 decreases. However, since it is main amplifier 10 that primarily amplifies input signal Sin, the decrease in efficiency of peak amplifiers 12 and 14 has a relatively small impact when viewed as a whole of the Doherty amplifier circuit.

In Doherty amplifier circuit 104 of the second embodiment, as illustrated in FIG. 14, two-stage matching circuit 30a is used as matching circuits 30 and 32, and one-stage matching circuit 30b is used as matching circuit 31. As illustrated in FIG. 15, the gain of peak amplifier 12 is larger than that of Doherty amplifier circuit 110 of the first comparative example. Thus, the step of the total gain when input power Pin is around power P2 is reduced. A step ΔG3 of the total gain is generated around power P3. Thus, the AM/AM characteristics are deteriorated compared to Doherty amplifier circuit 102 of the first embodiment. However, by using two-stage matching circuit 30a in matching circuit 32, the efficiency of peak amplifier 14 improves, resulting in improving an overall efficiency compared to Doherty amplifier circuit 102 in the first embodiment.

Table 1 illustrates characteristics (efficiency, distortion, and phase difference) of the respective Doherty amplifier circuits 110, 112, 102, and 104. The numbers 30 to 32 are the numbers of stages of matching circuits 30 to 32. Reference numeral 1 denotes one-stage matching circuit 30b, and reference numeral 2 denotes two-stage matching circuit 30a. The “efficiency” represents drain efficiency, the “distortion” represents AM/AM characteristics, and the “phase difference” represents phase difference between matching circuits 30 to 32. A in each characteristic indicates that the characteristic is good. B indicates that the characteristics are good, although not as good as A. B-indicates slightly worse characteristics than B. C indicates poor characteristics. D indicates very poor characteristics.

TABLE 1

| | | | | | | PHASE |
|---|---|---|---|---|---|---|
| | 30 | 31 | 32 | EFFICIENCY | DISTORTION | DIFFERENCE |
| 110 | 2 | 2 | 2 | A | C | A |
| 112 | 1 | 2 | 2 | D | D | B |
| 102 | 2 | 1 | 1 | B− | A | B |
| 104 | 2 | 1 | 2 | B | B | B |

As illustrated in table 1, in the first comparative example, since Doherty amplifier circuit 110 uses two-stage matching circuit 30a from matching circuit 30 to 32, the efficiency is A. The distortion is C. Since matching circuits 30 to 32 are the same, there is almost no phase difference between matching circuits 30 to 32, and the phase difference is A.

In the second comparative example, Doherty amplifier circuit 112 has lower efficiency and distortion than Doherty amplifier circuit 110, and the efficiency and the distortion are D. Since the number of stages of matching circuits 30 to 32 is different, the phase difference of Doherty amplifier circuit 112 is lower than that of Doherty amplifier circuit 110. However, since the phase can be adjusted, the phase difference is not at a level that causes a problem.

In the first embodiment, Doherty amplifier circuit 102 has lower efficiency than Doherty amplifier circuit 110 and the efficiency is B-, but the distortion is A. The phase difference is B. In the second embodiment, Doherty amplifier circuit 104 has slightly higher efficiency than Doherty amplifier circuit 102 in the first embodiment and the efficiency is B. Doherty amplifier circuit 104 has slightly lower distortion than Doherty amplifier circuit 102 and the distortion is B, but Doherty amplifier circuit 104 has higher distortion than Doherty amplifier circuit 110.

### DESCRIPTION OF EMBODIMENT

According to the first embodiment and the second embodiment, matching circuit 30 (first matching circuit) is connected between divider 16 and main amplifier 10. Matching circuit 31 (second matching circuit) is connected between divider 16 and peak amplifier 12. As illustrated in FIG. 9, in the operation band, the absolute value of a return loss RL2 seen from divider 16 toward matching circuit 31 is larger than the absolute value of a return loss RL1 seen from divider 16 toward matching circuit 30. As a result, as illustrated in FIG. 10, the gain of peak amplifier 12 can be improved. Thus, as illustrated in FIG. 15, the step of the total gain can be reduced, and the distortion can be suppressed. Thus, the characteristics can be improved.

The absolute value of return loss RL2 may be larger than the absolute value of return loss RL1 at any frequency of the operation band. At any frequency of the operation band, the absolute value of return loss RL2 can be larger than the absolute value of return loss RL1 by 1 dB or more, and can be larger than 5 dB or more. Thus, the gain of peak amplifier 12 can be further improved. When the absolute value of return loss RL1 is too small, the gain of main amplifier 10 deteriorates excessively. From this viewpoint, the absolute value of return loss RL1 can be 3 dB or more at any frequency of the operation band.

As illustrated in FIG. 5 to FIG. 7, the impedance seen from main amplifier 10 toward matching circuit 30 is capacitive at a frequency 2f twice a center frequency of the operation band. The impedance seen from peak amplifier 12 toward matching circuit 31 is inductive. Thus, since the efficiency of main amplifier 10 can be improved, the efficiency of the entire amplifier is improved. Thus, the characteristics can be further improved.

In the Smith chart, when the angle in the counterclockwise direction from the open position is defined as phase, the phase of impedance Z6(2f) seen from main amplifier 10 toward matching circuit 30 can be −180° to −20°, and can be −180° to −90°. Thus, the efficiency of main amplifier 10 can be improved. The phase of impedance Z6(2f) seen from peak amplifier 12 toward matching circuit 31 can be 0° to 90°, and can be 20° to 70°. Thus, the gain of peak amplifier 12 can be improved.

The Doherty amplifier circuit may be a two-way Doherty amplifier circuit in which peak amplifier 14 is not provided. In the case of a three-way Doherty amplifier circuit including peak amplifier 14 and matching circuit 32 (third matching circuit), the balance between efficiency and distortion is important. Thus, the absolute value of return loss RL2 can be larger than the absolute value of return loss RL1. As a result, it is possible to improve the characteristics of the three-way Doherty amplifier circuit.

In Doherty amplifier circuit 102 of the first embodiment, the absolute value of a return loss RL3 seen from divider 16 toward matching circuit 32 is larger than the absolute value of return loss RL1 seen from divider 16 toward matching circuit 30. As a result, the gain of peak amplifier 14 can be improved as illustrated in FIG. 10. Thus, as illustrated in FIG. 15, the step of the total gain can be reduced, and the distortion can be suppressed.

At any frequency of the operation band, the absolute value of return loss RL3 can be larger than the absolute value of return loss RL1 by 1 dB or more, or 5 dB or more. The absolute value of return loss RL1 can be 3 dB or more at any frequency of the operation band.

At frequency 2f, the impedance seen from peak amplifier 14 toward matching circuit 32 is inductive. Thus, the distortion can be further suppressed.

In Doherty amplifier circuit 104 of the second embodiment, the absolute value of return loss RL3 seen from divider 16 toward matching circuit 32 is smaller than the absolute value of return loss RL2 seen from divider 16 toward matching circuit 31. Thus, the efficiency of peak amplifier 14 can be improved.

The absolute value of return loss RL3 may be smaller than the absolute value of return loss RL2 at any frequency of the operation band. At any frequency of the operation band, the absolute value of return loss RL3 can be smaller than the absolute value of return loss RL2 by 1 dB or more, or 5 dB or more. At any frequency of the operation band, the absolute value of return loss RL3 can be 3 dB or more.

At frequency 2f, the impedance seen from peak amplifier 14 toward matching circuit 32 is capacitive. Thus, the efficiency can be further improved.

The circuit configuration of matching circuits 30 to 32 is not limited to the configuration of FIG. 2 and FIG. 3, and may be any configuration as long as the return loss has a desired value. Two-stage matching circuit 30a is used as matching circuit 30, and one-stage matching circuit 30b is used as matching circuit 31. As a result, the absolute value of return loss RL2 can be larger than the absolute value of return loss RL1. In addition, at the frequency 2f, the impedance seen from main amplifier 10 toward matching circuit 30 can be capacitive, and the impedance seen from peak amplifier 12 toward matching circuit 31 can be inductive. Thus, the characteristics can be further improved.

As in Doherty amplifier circuit 102 of the first embodiment, matching circuit 32 may use one-stage matching circuit 30b. As a result, the absolute value of return loss RL3 can be larger than the absolute value of return loss RL1. Further, at frequency 2f, the impedance seen from peak amplifier 14 toward matching circuit 32 can be inductive.

As in Doherty amplifier circuit 104 of the second embodiment, matching circuit 32 may use two-stage matching circuit 30a. As a result, the absolute value of return loss RL3 can be smaller than the absolute value of return loss RL2. Further, at frequency 2f, the impedance seen from peak amplifier 14 toward matching circuit 32 can be capacitive.

As illustrated in FIG. 8, in two-stage matching circuit 30a, the absolute value of impedance Z6(f) (first impedance) seen from inductor L3 toward gate G at the center frequency of the operation band is set as |Z6(f)|. The absolute value of impedance Z2(f) (second impedance) seen from inductor L1 toward node N1 is set as |Z2(f)|. The absolute value of impedance Z1(f) (third impedance) seen from divider 16 toward inductor L1 is set as |Z1(f)|. The ratio |Z2(f)|/|Z6(f)| of |Z2(f)| to |Z6(f)| is referred to as a first ratio R1. The ratio |Z1(f)|/|Z2(f)| of |Z1(f)| to |Z2(f)| is referred to as a second ratio R2. When |Z6(f)|, |Z2(f)|, and |Z1(f)| are 0.15 Ω, 30Ω, and 50Ω, respectively, first ratio R1=200 and second ratio R2=1.67 are satisfied, and the ratio R1/R2 of first ratio R1 to second ratio R2 is approximately 120.

As illustrated in FIG. 4, in one-stage matching circuit 30b, the absolute value of impedance Z6(f) (fourth impedance) seen from inductor L5 toward gate G at the center frequency of the operation band is set as |Z6(f)|. The absolute value of impedance Z7(f) (fifth impedance) seen from inductor L4 toward node N3 is set as |Z7(f)|. The absolute value of impedance Z1(f) (sixth impedance) seen from divider 16 toward inductor L4 is set as |Z1(f)|. The ratio |Z7(f)|/|Z6(f)| of |Z7(f)| with respect to |Z6(f)| is referred to as a third ratio R3. The ratio |Z1(f)|/|Z7(f)| of |Z1(f)| with respect to |Z7(f)| is referred to as a fourth ratio R4. When |Z6(f)|, |Z7(f)|, and |Z1(f)| are 0.15 Ω, 3Ω and 50Ω, respectively, third ratio R3=20 and fourth ratio R4=16.7 are satisfied, and the ratio R3/R4 of third ratio R3 to fourth ratio R4 is approximately 1.20.

As described above, the ratio R1/R2 is made larger than the ratio R3/R4. Thus, it is possible to improve the efficiency of main amplifier 10 in which matching circuit 30 is two-stage matching circuit 30a, and to improve the gain of peak amplifier 12 in which matching circuit 31 is one-stage matching circuit 30b. The ratio R1/R2 can be twice or more, 10 times or more, or 50 times or more of the ratio R3/R4. From the perspective of not making the ratio R1/R2 too large, the ratio R1/R2 can be 1000 times or less of the ratio R3/R4.

In two-stage matching circuit 30a, first ratio R1 is larger than second ratio R2. Thus, the efficiency of main amplifier 10 in which matching circuit 30 is two-stage matching circuit 30a can be improved. First ratio R1 can be twice or more, 10 times or more, or 100 times or more of second ratio R2. From the perspective of not making first ratio R1 too large, first ratio R1 can be 1000 times or less of second ratio R2.

From the perspective of rotating the phase from impedance Z3(2f) to impedance Z4(2f) in FIG. 7 and reducing the shift from impedance Z6(f) to impedance Z5(f) in FIG. 8, the inductance of inductor L2 can be larger than the inductance of inductor L3, and can be twice or more the inductance of inductor L3. In FIG. 8, from the perspective of reducing the shift from impedance Z5(f) to impedance Z4(f) and shifting from impedance Z3(f) to impedance Z2(f), the capacitance of capacitor C1 can be larger than the capacitance of capacitor C2, and can be 1.5 times or more the capacitance of capacitor C2.

In one-stage matching circuit 30b, third ratio R3 can be 0.1 times to 10 times, 0.2 times to 5 times, or 0.5 times to 2 times of fourth ratio R4. Thus, it is possible to improve the gain of peak amplifier 12 in which matching circuit 31 is one-stage matching circuit 30b.

### Third Embodiment

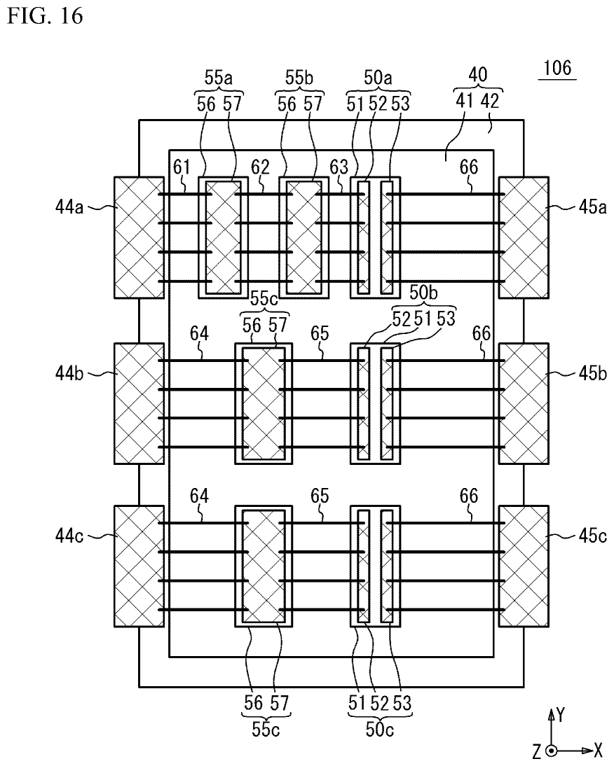

A third embodiment and its modification 1 are examples of the semiconductor device for the Doherty amplifier circuit of the first embodiment and the second embodiment. FIG. 16 is a plan view of a semiconductor device according to the third embodiment. In FIG. 16, the lid of a package 40 is not illustrated. The thickness direction of a base 41 of package 40 is defined as a Z direction, the direction from leads 44a to 44c to leads 45a to 45c is defined as an X direction, and the direction orthogonal to the X direction and the Z direction is defined as a Y direction.

As illustrated in FIG. 16, in a semiconductor device 106 of example 3, package 40 includes base 41 at least an upper surface of which is conductive, a frame body 42, and leads 44a to 44c and 45a to 45c. Base 41 is a conductor substrate such as a copper-molybdenum laminated substrate, for example. A reference potential such as a ground potential is supplied to base 41. Semiconductor chips 50a to 50c and capacitive components 55a to 55c are mounted on base 41. Frame body 42 is provided on base 41 so as to surround semiconductor chips 50a to 50c and capacitive components 55a to 55c. Frame body 42 is a dielectric layer made of a resin such as a glass epoxy resin or a ceramic.

Leads 44a to 44c are provided on a side of frame body 42 in a negative direction of the X direction. Leads 45a to 45c are provided on a side of frame body 42 in a positive direction of the X direction. Leads 44a to 44c and 45a to 45c are metal layers or metal plates made of, for example, copper. Signals S1 to S3 are input to leads 44a to 44c, respectively, and signals S4 to S6 are output from leads 45a to 45c, respectively.

Each of semiconductor chips 50a to 50c includes a semiconductor substrate 51, pads 52 and 53 provided on the upper surface of semiconductor substrate 51, and an electrode provided on the lower surface of semiconductor substrate 51. Pads 52 and 53 and the electrode on the lower surface of semiconductor substrate 51 are a gate electrode, a drain electrode, and a source electrode, respectively, and pads 52 and 53 are an input pad and an output pad, respectively. Semiconductor substrate 51 is provided with transistors Q1 to Q3 illustrated in FIG. 1. When transistors Q1 to Q3 are GaN HEMTs, semiconductor substrate 51 is, for example, a silicon carbide (SiC) substrate, a sapphire substrate, or a gallium nitride (GaN) substrate. When transistors Q1 to Q3 are LDMOSs, semiconductor substrate 51 is, for example, a silicon (Si) substrate. Pads 52 and 53 and the electrode are metal layers such as gold layers.

Capacitive components 55a to 55c include a dielectric substrate 56, an electrode 57 provided on the upper surface of dielectric substrate 56, and an electrode provided on the lower surface of dielectric substrate 56. Electrode 57 and the electrode on the lower surface sandwiching dielectric substrate 56 form a capacitor. Dielectric substrate 56 is, for example, an alumina substrate or a barium titanate substrate. Electrode 57 is a metal layer such as a gold layer.

Two capacitive components 55a and 55b are provided between lead 44a and semiconductor chip 50a. One capacitive component 55c is provided between lead 44b and semiconductor chip 50b, and one capacitive component 55c is provided between lead 44c and semiconductor chip 50c.

Bonding wires 61 electrically connect lead 44a and electrode 57 of capacitive component 55a. Bonding wires 62 electrically connect electrode 57 of capacitive component 55a and electrode 57 of capacitive component 55b. Bonding wire 63 electrically connect electrode 57 of capacitive component 55b and pad 52 of semiconductor chip 50a. Bonding wires 64 electrically connects lead 44b (and 44c) and electrode 57 of capacitive component 55c. Bonding wires 65 electrically connect electrode 57 of capacitive component 55c and pad 52 of semiconductor chip 50b (and 50c). Bonding wires 66 electrically connect pads 53 of semiconductor chips 50a to 50c to leads 45a to 45c, respectively. Bonding wires 61 to 66 are metal wires such as gold wires or aluminum wires.

Bonding wires 61 to 65 correspond to inductors L1 to L5 of FIG. 13, respectively. Capacitive components 55a to 55c correspond to capacitors C1 to C3 of FIG. 13, respectively. Thus, bonding wires 61 to 63 and capacitive components 55a and 55b form two-stage matching circuit 30a, and bonding wires 64 and 65 and capacitive component 55c form one-stage matching circuit 30b.

### Modification 1 of Third Embodiment

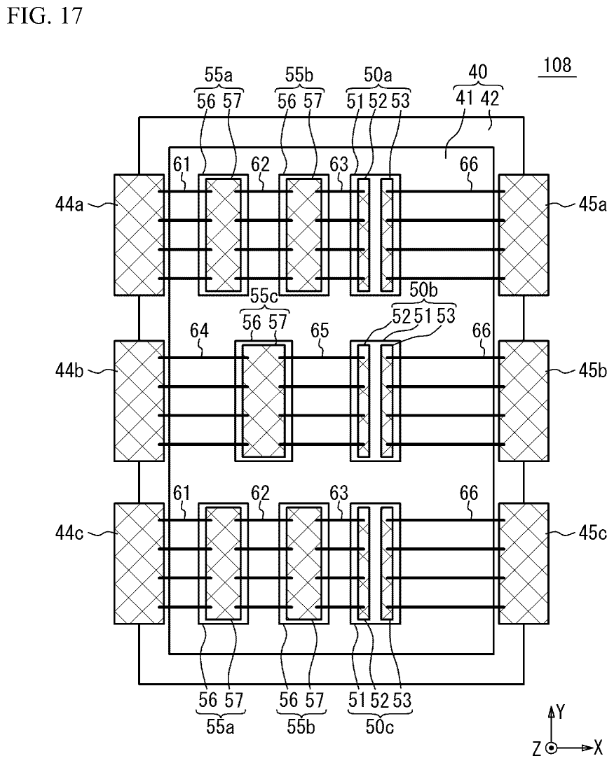

FIG. 17 is a plan view of a semiconductor device according to a first modification of the third embodiment. As illustrated in FIG. 17, in a semiconductor device 108 of the modification 1 of the third embodiment, capacitive components 55a and 55b are provided between lead 44c and semiconductor chip 50c. Bonding wires 61 electrically connect lead 44c and electrode 57 of capacitive component 55a. Bonding wires 63 electrically connect electrode 57 of capacitive component 55b and pad 52 of semiconductor chip 50c. The other structure is the same as that of FIG. 16 of the third embodiment, and the description thereof is omitted.

According to the third embodiment and first modification thereof, as illustrated in FIGS. 16 and 17, semiconductor chip 50a (first semiconductor chip) includes main amplifier 10, semiconductor chip 50b (second semiconductor chip) includes peak amplifier 12, and semiconductor chip 50c (third semiconductor chip) includes peak amplifier 14.

Capacitors C1 to C3 correspond to capacitive components 55a to 55c, respectively, and are mounted on base 41, and first ends thereof are electrically connected to base 41. Inductor L1 corresponds to bonding wires 61, and the first end is electrically connected to lead 44a (first input lead) and the second end is electrically connected to the second end of capacitor C1. Inductor L2 corresponds to bonding wires 62, and the first end is electrically connected to the second end of capacitor C1, and the second end is electrically connected to the second end of capacitor C2. Inductor L3 corresponds to bonding wires 63, and the first end is electrically connected to the second end of capacitor C2, and the second end is electrically connected to pad 52 (input pad) of semiconductor chip 50a. Inductor L4 corresponds to bonding wires 64, and the first end is electrically connected to lead 44b (second input lead), and the second end is electrically connected to the second end of capacitor C3. Inductor L5 corresponds to bonding wires 65, and the first end is electrically connected to the second end of capacitor C3, and the second end is electrically connected to pad 52 (input pad) of semiconductor chip 50b.

Thus, matching circuit 30 can be used as two-stage matching circuit 30a, and matching circuit 31 can be used as one-stage matching circuit 30b. Thus, the characteristics of Doherty amplifier circuits 102 and 104 of the first embodiment and the second embodiment can be improved.

Although the three-way Doherty amplifier circuit has been described as an example, the Doherty amplifier circuit may be a two-way Doherty amplifier circuit in which peak amplifier 14 and matching circuit 32 are not provided. Further, the Doherty amplifier circuit may be an N-way Doherty amplifier circuit in which N is four or more. In this case, N-1 peak amplifiers may be provided.

The embodiments disclosed herein are to be considered in all respects as illustrative and not restrictive. The scope of the present disclosure is indicated by the scope of the claims, not by the meaning described above, and is intended to include all modifications within the scope and meaning equivalent to the scope of the claims.

What is claimed is:

1. A Doherty amplifier circuit comprising:
a divider that divides a received input signal into a first signal and a second signal;
a main amplifier that amplifies the first signal and outputs an amplified signal as a fourth signal;
a first peak amplifier that amplifies the second signal and outputs an amplified signal as a fifth signal;
a combiner that combines the fourth signal and the fifth signal into a combined signal and outputs the combined signal as an output signal to an output terminal;
a first matching circuit connected between the divider and the main amplifier; and
a second matching circuit connected between the divider and the first peak amplifier, wherein
in an operation band, an absolute value of a return loss seen from the divider toward the second matching circuit is larger than an absolute value of a return loss seen from the divider toward the first matching circuit.

2. The Doherty amplifier circuit according to claim 1, wherein
at a frequency twice a center frequency of the operation band, an impedance seen from the main amplifier toward the first matching circuit is capacitive, and
at the frequency twice the center frequency, an impedance seen from the first peak amplifier toward the second matching circuit is inductive.

3. The Doherty amplifier circuit according to claim 1, wherein
the first matching circuit is a two-stage matching circuit that includes a first inductor having a first end electrically connected to the divider and a second end electrically connected to a first node, a second inductor having a first end electrically connected to the first node and a second end electrically connected to a second node, a third inductor having a first end electrically connected to the second node and a second end electrically connected to the main amplifier, a first capacitor shunt-connected to the first node, and a second capacitor shunt-connected to the second node, and
the second matching circuit is a one-stage matching circuit that includes a fourth inductor having a first end electrically connected to the divider and a second end electrically connected to a third node, a fifth inductor having a first end electrically connected to the third node and a second end electrically connected to the first peak amplifier, and a third capacitor shunt-connected to the third node.

4. The Doherty amplifier circuit according to claim 3, wherein
when, in the operation band, a ratio of an absolute value of a second impedance seen from the first inductor toward the first node to an absolute value of a first impedance seen from the third inductor toward the main amplifier is a first ratio, a ratio of an absolute value of a third impedance seen from the divider toward the first inductor to the absolute value of the second impedance is a second ratio, a ratio of an absolute value of a fifth impedance seen from the fourth inductor toward the third node to an absolute value of a fourth impedance seen from the fifth inductor toward the first peak amplifier is a third ratio, and a ratio of an absolute value of a sixth impedance seen from the divider toward the fourth inductor to the absolute value of the fifth impedance is a fourth ratio,
a ratio of the first ratio to the second ratio is larger than a ratio of the third ratio to the fourth ratio.

5. The Doherty amplifier circuit according to claim 4, wherein the first ratio is larger than the second ratio.

6. The Doherty amplifier circuit according to claim 1, further comprising:
a second peak amplifier that amplifies a third signal and outputs an amplified signal as a sixth signal; and
a third matching circuit connected between the divider and the second peak amplifier, wherein
an input power of the input signal for turning on the second peak amplifier is larger than an input power of the input signal for turning on the first peak amplifier,
the divider divides the input signal into the first signal, the second signal, and the third signal, and
the combiner combines the fourth signal, the fifth signal, and the sixth signal into a combined signal and outputs the combined signal as the output signal to the output terminal.

7. The Doherty amplifier circuit according to claim 6, wherein,
in the operation band, an absolute value of a return loss seen from the divider toward the third matching circuit is larger than an absolute value of a return loss seen from the divider toward the first matching circuit.

8. The Doherty amplifier circuit according to claim 7, wherein
at a frequency twice a center frequency of the operation band, an impedance seen from the main amplifier toward the first matching circuit is capacitive,
at the frequency twice the center frequency, an impedance seen from the first peak amplifier toward the second matching circuit is inductive, and
at the frequency twice the center frequency, an impedance seen from the second peak amplifier toward the third matching circuit is inductive.

9. The Doherty amplifier circuit according to claim 6, wherein
in the operation band, an absolute value of a return loss seen from the divider toward the third matching circuit is smaller than an absolute value of a return loss seen from the divider toward the second matching circuit.

10. The Doherty amplifier circuit according to claim 9, wherein
at a frequency twice a center frequency of the operation band, an impedance seen from the main amplifier toward the first matching circuit is capacitive,
at the frequency twice the center frequency, an impedance seen from the first peak amplifier toward the second matching circuit is inductive, and
at the frequency twice the center frequency, an impedance seen from the second peak amplifier toward the third matching circuit is capacitive.

11. A semiconductor device for a Doherty amplifier circuit, the semiconductor device comprising:
a package comprising a base, a first input lead, and a second input lead;
a first semiconductor chip mounted on the base, the first semiconductor chip including a main amplifier that amplifies a first signal divided from an input signal;
a second semiconductor chip mounted on the base, the second semiconductor chip including a first peak amplifier that amplifies a second signal divided from the input signal;
a first capacitor mounted on the base, the first capacitor having a first end electrically connected to the base;
a second capacitor mounted on the base, the second capacitor having a first end electrically connected to the base;
a third capacitor mounted on the base, the third capacitor having a first end electrically connected to the base;
a first inductor having a first end electrically connected to the first input lead and a second end electrically connected to a second end of the first capacitor;
a second inductor having a first end electrically connected to the seocnd end of the first capacitor and a second end electrically connected to a second end of the second capacitor;
a third inductor having a first end electrically connected to the second end of the second capacitor and a second end electrically connected to an input pad of the first semiconductor chip;
a fourth inductor having a first end electrically connected to the second input lead and a second end electrically connected to the second end of the third capacitor; and
a fifth inductor having a first end electrically connected to the second end of the third capacitor and a second end electrically connected to an input pad of the second semiconductor chip.
